(19) United States
(12) Patent Application Publication
(10) Pub. No.: US 2010/0007335 A1
(43) Pub. Date: Jan. 14, 2010

(54) Measuring Apparatus

(76) Inventors: Peter Kaluza, Rieden (DE); Richard Schmidt, Baiersdorf (DE); Christian Widmann, Poppenricht (DE)

Correspondence Address: HARNESS, DICKEY & PIERCE, P.L.C., P.O.BOX 8910, RESTON, VA, 20195, US

(21) Appl. No.: 12/309,604

(22) PCT Filed: Jul. 26, 2006
(86) PCT No.: PCT/DE2006/001291

§ 371 Date: Jan. 23, 2009

(51) Int. Cl. G01R 19/00

(52) U.S. Cl. 324/123 R

(57) ABSTRACT

A measuring apparatus, in particular for measuring current, is provided. In at least one embodiment, the measuring apparatus includes a sensor and an evaluation device which is coupled or can be coupled thereto, in which the coupling is effected contactlessly, in particular by way of a transponder interface. As such, on the one hand current can be measured in a reaction-free manner, wherein on the other hand the resulting measuring apparatus can be used in a particularly flexible and versatile manner on account of the maneuverability of the components with respect to one another and on account of the relatively large possible distance between the two parts of the transponder interface.

### PRIORITY STATEMENT

This application is the national phase under 35 U.S.C. § 371 of PCT International Application No. PCT/DE2006/001291 which has an International filing date of Jul. 26, 2006, which designated the United States of America, the entire contents of which are hereby incorporated herein by reference.

### FIELD

At least one embodiment of the invention generally relates to a measuring device. For example, at least one embodiment relates to a measuring device for electrically isolated measurement of DC and/or AC currents, especially a measuring apparatus for measuring DC currents where there is a high insulation resistance.

### BACKGROUND

The electrically isolated measurement of AC currents is possible relatively easily in a variety of ways. In the prior art, “Rogowski coils”, which are transformer-type devices employing measuring transformers etc., are known for this purpose. On the other hand, the electrically isolated measurement of DC currents is far more complex. To the best knowledge of the applicant, only two methods are essentially used today for this purpose: one method is based on introducing a series resistor (shunt) in the current path and measuring the current-dependent voltage drop; the other method is based on measuring the current-dependent magnetic field using a magnetic field sensor, for instance a Hall sensor or what are known as AMR/GMR sensors.

The problem with measuring across a shunt resistor is the direct electrical connection of the measuring points to the potential of the current-carrying conductor. This requires electronic evaluation circuitry having both an electrically isolated power supply and an electrically isolated signal path for transmitting the measurements.

Using magnetic field sensors to measure the current has the advantage of non-interaction, i.e. there is no need to introduce a series resistor in the current path to measure the current. As such, this thereby avoids the disadvantages associated with making a break in the line, the power loss occurring across the shunt resistor and the change in the line impedance.

In addition, using magnetic field sensors benefits from the inherent advantages of electrical isolation that are enjoyed e.g. when using transformers.

The problem with the magnetic field measurement, however, is the sensitivity of such magnetic field sensors to external fields and interference fields. Suitable screening measures or field concentrators must be used to counteract this effect. In particular, it has proved necessary to position the magnetic field sensors as close as possible to the current-carrying conductor, because the intensity of the magnetic field of a current-carrying conductor is known to decrease sharply with distance (H˜1/(2πr)).

### SUMMARY

At least one embodiment of the invention defines a measuring apparatus that not only can be operated substantially with no interaction but also is essentially immune to external fields and interference fields.

In at least one embodiment, a measuring apparatus, in particular a measuring apparatus for measuring current, includes a sensor and an evaluation device which is coupled or can be coupled thereto, that the coupling between sensor and evaluation device is effected without contact.

An advantage of at least one embodiment of the invention lies in the fact that this coupling creates the opportunity of transferring power and/or data, for instance measurements in the form of electronic signals, without contact.

In at least one embodiment, for coupling purposes, the sensor has a first transponder interface and the evaluation device has a second transponder interface. Coupling is then based on the transponder principle: the coupling is a transponder coupling, in particular based on inductive or electromagnetic (radio) coupling.

If the first transponder interface assigned to the sensor is a passive transponder interface, this first transponder interface and/or the sensor together does not have its own power supply, thereby substantially avoiding interactions with the electrical values to be measured. The first transponder interface receives the power required for the measurement via the second transponder interface of the evaluation device.

The sensor preferably includes a differential amplifier, which, in an advantageous embodiment, is coupled or can be coupled to a line via a shunt resistor. In such a configuration, the measuring apparatus according to at least one embodiment of the invention can also be used for a measurement across a shunt resistor, which otherwise tends not to be considered in connection with zero or low interaction measurement because of unavoidable interactions with the electrical values to be measured.

A magnetic field sensor, which is coupled or can be coupled to the conductor, is an alternative to the shunt resistor in at least one embodiment. Using such a magnetic field sensor, in particular in an embodiment as a GMR sensor, creates the opportunity of measuring a current flowing through the conductor without any interactions, or at most negligible interactions, with the conductor and the measured electrical values.

A particularly preferred embodiment is obtained if the sensor and evaluation device are each implemented as a separate physical unit. Then the sensor having the magnetic field sensor can be assigned to the conductor and the evaluation device can be assigned to the sensor by suitable positioning.

At least some of the individual embodiments, in general, have the advantage that the relatively large distance of the coupling based on the transponder principle also allows both the sensor and the evaluation device to be implemented in an encapsulated and shock-proof form. In addition, the transponder coupling also allows a certain range of mechanical movements between the sensor and the line. In certain embodiments, rotational movements or physical changes in location can also be implemented.

For a sensor having a shunt resistor, the sensor together with this shunt resistor can form a physical unit, for which no cable connections whatsoever are required between the evaluation unit and the live region of the conductor measured in the measurement.

In addition, the sensor together with its transponder interface form a safe measuring point, from which readings can be taken using mobile devices. An electronic circuit assigned to the sensor can also comprise a piece of identification information that is non-volatile in particular, as is known from other transponder applications. By this, it is possible for a higher-level system to identify uniquely an individual measuring point, for instance the respective evaluation device, from a group of measuring points. This is particularly useful when replacing components or if the components or measuring points are moveable.

When measuring the current using a magnetic field sensor, in particular a GMR sensor, it is also advantageous for it to be possible to arrange the current sensor in an optimally close position to the conductor carrying or intended to carry the current, to a line, a conductor track or a power rail or the like. Furthermore, the insulation between sensor and conductor only needs to be a purely functional isolation having a very low dielectric strength.

In addition, single-pole contact with the conductor is possible, because the safety function is performed by the transponder interface. Finally, the magnetic field sensor operates with completely no interaction unlike the alternative embodiment having the shunt resistor.

The unavoidable additional resistance of the line with the shunt resistor and the resultant power loss do not occur with the magnetic field sensor. In addition, such a magnetic field sensor can easily be arranged in the vicinity of the respective conductor, and where the conductor is a power rail can even be retrofitted without the rail being removed.

Finally, magnetic field sensors in their embodiment as a GMR sensor, which is based on an operating principle that depends on the field direction (gradient field sensors), have advantages for the application as current sensors because they are extremely stable compared with large magnetic fields and also the operating principle of the dependence on the magnetic field direction can be exploited by arranging a plurality of individual sensors specifically into a bridge circuit in order to achieve high immunity to external interference fields.

The patent claims submitted with the application are proposed formulations that do not prejudice achieving patent protection. The applicant reserves the right to claim yet further combinations of features hitherto only disclosed in the description and/or drawings.

The example embodiment or each example embodiment shall not be seen as restricting the invention. In fact numerous variations and modifications are possible within the scope of the present disclosure, in particular such variants, elements and combinations that, for example, by combining or modifying individual features or elements or method steps described in connection with the general or specific description part and contained in the claims and/or the drawings can be gathered by the person skilled in the art with regard to achieving the objective and that lead to a new subject matter or new method steps or sequences of method steps by combinable features, including where they concern manufacturing methods for instance.

Back-references used in subclaims point to the further development of the subject matter of the main claim by the features of the respective subclaim; they shall not be seen as relinquishing achieving independent protection of the subject matter for the feature combinations of the referred-back subclaims. In addition, with regard to interpreting the claims, where a feature is specified more precisely in a subsequent claim, it must be assumed that such a restriction does not exist in each of the preceding claims.

Since the subject matters of the subclaims in relation to the prior art on the priority date may form separate and independent inventions, the applicant reserves the right to make them the subject matter of independent claims or declarations of division. They may also contain independent inventions, which have an embodiment that is independent of the subject matters of the preceding subclaims.

### BRIEF DESCRIPTION OF THE DRAWINGS

An example embodiment of the invention is described in greater detail below with reference to the drawings. Corresponding objects or elements are denoted by the same references in all the figures. In the drawings:

FIG. 1 shows a measuring apparatus for current measurement known in the prior art,

FIG. 2 shows a device for contactless current measurement using a magnetic field sensor,

FIG. 3 shows a first embodiment of a measuring apparatus according to the invention having a contactless coupling between a part of the measuring apparatus acting as a sensor and a part of the same measuring apparatus acting as an evaluation device,

FIG. 4 shows an alternative embodiment of the embodiment shown in FIG. 3 using a GMR or magnetic field sensor, and

FIG. 5 shows a schematically simplified diagram of the embodiment of FIG. 4, where the sensor and the evaluation device are each implemented as a separate physical unit.

### DETAILED DESCRIPTION OF THE EXAMPLE EMBODIMENTS

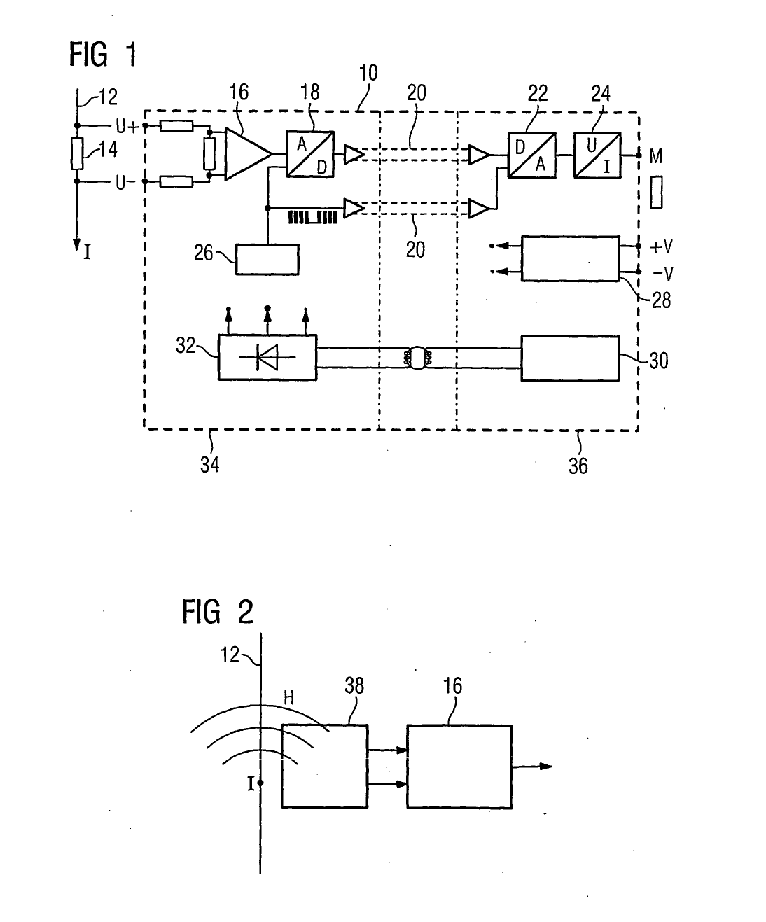

FIG. 1 shows a measuring apparatus 10 known in the prior art for measuring the current I flowing through a conductor 12 (current measurement). The known measuring apparatus is based on a shunt resistor 14 present in the conductor 12, across which resistor the voltage drop is measured and transferred via a differential amplifier 16 to an analog-to-digital converter 18, from where the data encoding the measured current is transferred in sequential form e.g. via an optical fiber 20 to a digital-to-analog converter 22 and from there to a voltage-current converter 24. The apparatus 10 also comprises an oscillator 26, a voltage regulator 28, a sine wave generator 30 and a rectifier/filter 32 which is fed from the generator and provided for the power supply. The measuring apparatus 10 as a whole is divided into a first part 34 and a second part 36, where the first part 34 performs the sensor function and is physically assigned to the conductor 12, and where the second part 36 performs the evaluation-device function and can be arranged remotely from the first part 34 acting as the sensor.

FIG. 2 shows in a simplified diagram the use of a magnetic field sensor 38 for current measurement, whose output is connected to a differential amplifier 16, a servo circuit or the like. The magnetic field sensor 38, which is implemented in particular in a form as a measuring bridge containing a plurality of individual magnetic field sensors (gradient field sensor), measures the magnetic field H around the conductor 12. According to the relationships known per se, the current I can be derived from the strength of the magnetic field, so that the current measurement actually intended is possible.

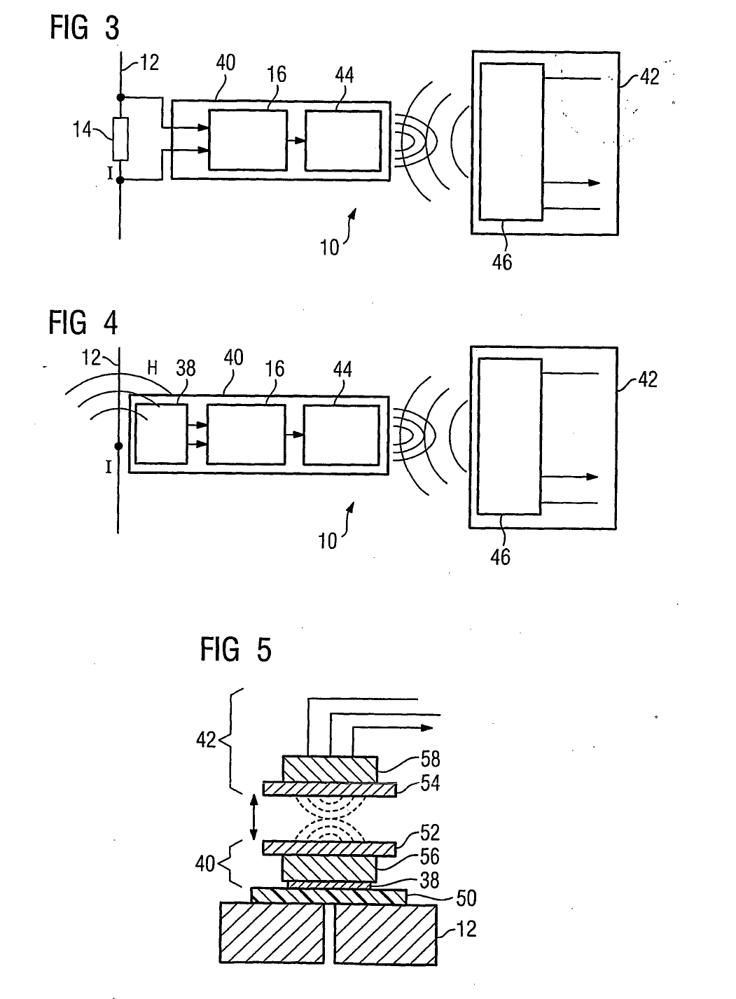

FIG. 3 and FIG. 4 show the implementation according to an embodiment of the invention of the measuring apparatus, in which a first part, acting as a sensor 40, of the measuring apparatus denoted as a whole by 10, is coupled without contact to a second part, acting as an evaluation device 42, of the measuring apparatus 10. This contactless coupling is achieved by the fact that the part acting as the sensor 40 has a first transponder interface 44, and the part acting as the evaluation device 42 has a second transponder interface 46. The first transponder interface 44 assigned to the sensor 40 is preferably implemented so that the sensor 40 receives its power via the evaluation device 42 and its transponder components 46.

The embodiment shown in FIG. 3 is based on a measurement of a current I through a conductor 12 via a shunt resistor 14. The sensor 40 comprises a differential amplifier 16 for evaluating the voltage drop across the shunt resistor 14 and, if applicable, further elements (not shown) from the diagram in FIG. 1, which is more detailed in this respect.

FIG. 4 shows the embodiment in which the current is measured by measuring the magnetic field H generated by the current I. For this purpose, the sensor 40 (cf. FIG. 2) has a magnetic field sensor 38, if necessary in an embodiment as a measuring bridge containing a plurality of individual magnetic field sensors, and a differential amplifier 16, which, if applicable, in a similar way to the embodiments above for FIG. 3, may comprise further components from the diagram in FIG. 1, which is more detailed in this respect.

FIG. 5 shows an embodiment in which sensor 40 and evaluation device 42 are implemented as a separate physical unit and in which the sensor 40 comprises a GMR sensor as the magnetic field sensor 38 and is assigned to a conductor 12 in the form of a power rail, a conductor track or the like. An insulating layer 50 is provided between the magnetic field sensor 38 and the conductor 12, which acts as a functional isolation between conductor 12 and magnetic field sensor 38. Sensor 40 and evaluation device 42 are each constructed on a separate printed circuit board 52, 54, where in the diagram of FIG. 5, the representation of the printed circuit board 52, 54 also includes the representation of the respective transponder antenna.

The transponder interface, identified in FIG. 5 by the vertical double-ended arrow, is obtained between the printed circuit boards 52, 54 and the transponder antenna formed by them, at least partially in this respect. The sensor 40 and a sensor and transponder circuit 56 is mounted e.g. in the form of an ASIC on the printed circuit board 52 of the sensor 40. A GMR layer acting as a magnetic field sensor 38 can be applied directly to this circuit 56. The transponder circuit on the evaluation-device side, i.e. the second transponder interface 46, is mounted, in particular in the form of an ASIC 58, on the printed circuit board 54 of the evaluation device 42.

At least one embodiment of the present invention can be summarized as follows: a measuring apparatus 10, in particular for current measurement, is defined, having a sensor 40 and an evaluation device 42 which is coupled or can be coupled thereto, in which the coupling is effected without contact, in particular via a transponder interface 44, 46, so that not only is it possible to measure the current without interaction but the resulting measuring apparatus 10 can be used in a particularly flexible and versatile manner by virtue of the comparatively large distance possible between the two parts of the transponder interface 44, 46.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A measuring apparatus, comprising:
a sensor including a differential amplifier; and
an evaluation device, at least one of coupled and coupleable to the sensor, wherein for non-contact coupling of the sensor and the evaluation device, the sensor includes a first passive transponder interface and the evaluation device includes a second transponder interface, and wherein
the differential amplifier being at least one of coupled and coupleable to a conductor via a magnetic field sensor.

2. The measuring apparatus as claimed in claim 1, wherein the magnetic field sensor is implemented as a GMR sensor.

3. The measuring apparatus as claimed in claim 1,
wherein sensor and evaluation device are each implemented as separate physical units, and wherein the sensor, including the magnetic field sensor, is assigned to the conductor and wherein the sensor is assigned to the evaluation device by suitable positioning.

4-8. (canceled)

9. The measuring apparatus as claimed in claim 2, wherein sensor and evaluation device are each implemented as separate physical units, and wherein the sensor, including the magnetic field sensor, is assigned to the conductor and wherein the sensor is assigned to the evaluation device by suitable positioning.

10. The measuring apparatus of claim 1, wherein the measuring apparatus is for measuring current where there is a high insulation resistance.

11. The measuring apparatus of claim 2, wherein the measuring apparatus is for measuring current where there is a high insulation resistance.

12. The measuring apparatus of claim 3, wherein the measuring apparatus is for measuring current where there is a high insulation resistance.

13. The measuring apparatus of claim 9, wherein the measuring apparatus is for measuring current where there is a high insulation resistance.

14. The measuring apparatus of claim 1, wherein the coupling creates a conduit for transfer of at least one of power and data.

15. A sensor for a measuring apparatus, comprising:
a differential amplifier at least one of coupled and coupleable to a conductor via a magnetic field sensor; and
a passive transponder interface to couple the sensor to a transponder interface of an evaluation device of the measuring apparatus.

16. The sensor as claimed in claim 15, wherein the magnetic field sensor is implemented as a GMR sensor.

17. The sensor as claimed in claim 15, wherein the sensor and the evaluation device are each implemented as separate physical units.

18. An evaluation device for a measuring apparatus, comprising:
a transponder interface to couple, in a non-contact manner, the evaluation device to a passive transponder interface of a sensor of the measuring apparatus, wherein a differential amplifier of the sensor is at least one of coupled and coupleable to a conductor via a magnetic field sensor.

19. The evaluation device as claimed in claim 18, wherein the magnetic field sensor is implemented as a GMR sensor.

20. The evaluation device as claimed in claim 18, wherein the sensor and the evaluation device are each implemented as separate physical units.
